(19) United States
(12) Patent Application Publication
(10) Pub. No.: US 2016/0111603 A1
(43) Pub. Date: Apr. 21, 2016

(54) Indium Zinc Oxide for Transparent Conductive Oxide Layer and Methods of Forming Thereof

(71) Applicants: Intermolecular, Inc., San Jose, CA (US); Epistar Corporation, Hsinchu (TW)

(72) Inventors: Jianhua Hu, Palo Alto, CA (US); Ben Cardozo, Palo Alto, CA (US); Minh Huu Le, San Jose, CA (US); Sandeep Nijhawan, Los Altos, CA (US); J.H. Yeh, Hsinchu (TW)

(21) Appl. No.: 14/519,274

(22) Filed: Oct. 21, 2014

(51) Int. Cl. H01L 33/42; H01L 33/32; H01L 33/00

(52) U.S. Cl. CPC H01L 33/42; H01L 33/0075; H01L 33/32; H01L 2933/0016

(57) ABSTRACT

Provided are light emitting diodes (LEDs) and methods of fabricating such LEDs. Specifically, an LED has an epitaxial stack and current distribution layer disposed on and interfacing the epitaxial stack. The current distribution layer includes indium oxide and zinc oxide such that the concentration of indium oxide is between about 5% and 15% by weight. During fabrication, the current distribution layer is annealed at a temperature of less than about 500° C. or even at less than about 400° C. These low anneal temperature helps preserving the overall thermal budget of the LED while still yielding a current distribution layer having a low resistivity and low adsorption. A particular composition and method of forming the current distribution layer allows using lower annealing temperatures. In some embodiments, the current distribution layer is sputtered using indium oxide and zinc oxide targets at a pressure of less than 5 mTorr.

### BACKGROUND

A light-emitting diode (LED) is a two-lead semiconductor light source. A typical LED has a structure similar to that of a p-n junction diode. However, the LED also emits light when activated or, more specifically, when a voltage is applied to the leads of the LED. The voltage causes electrons to recombine with electron holes within the LED releasing energy in the form of photons. This release of energy is sometimes referred to as electroluminescence. The color or, more specifically, the wavelength of the emitted light is based on the energy band gap of the semiconductor used for constructing the LED. Modern LEDs are characterized by low power consumption, low heat generation, long operational life, shockproof, small volume, quick response, and other like properties. As a result LEDs have been widely adopted for various applications, such as light sources in displays. New designs of LEDs with further improvements of above recited characteristics and methods of fabricating such advanced LEDs are needed.

### SUMMARY

Provided are light emitting diodes (LEDs) and methods of fabricating such LEDs. Specifically, an LED has an epitaxial stack and current distribution layer disposed on and interfacing the epitaxial stack. The current distribution layer includes indium oxide and zinc oxide such that the concentration of indium oxide is between about 5% and 15% by weight. During fabrication, the current distribution layer is annealed at a temperature of less than about 500° C. or even at less than about 400° C. These low anneal temperatures help to preserve the overall thermal budget of the LED while still yielding a current distribution layer having a low resistivity and low absorption. Compositions and methods of forming the current distribution layer allow using lower annealing temperatures. In some embodiments, the current distribution layer is sputtered using indium oxide and zinc oxide targets at a pressure of less than 5 mTorr.

In some embodiments, methods of fabricating a light emitting diode involve forming a first layer using sputtering. Sputtering may be performed at a pressure of less than 5 mTorr. The first layer includes indium oxide and zinc oxide. The concentration of indium oxide in the first layer is between about 5% and 15% by weight or, more specifically, between about 8% and 12% by weight, such as about 10% by weight. The first layer may be formed on a surface of an epitaxial stack. In some embodiments, the surface includes p-doped gallium nitride. The surface may include gallium nitride. The methods may proceed with annealing the first layer at a temperature of less than about 500° C. (e.g., between about 100° C. and 500° C.) or, more specifically, at less than about 400° C. (e.g., between about 150° C. and 400° C.) or even at less than about 300° C. (e.g., between about 200° C. and 400° C.).

In some embodiments, forming the first layer comprises co-sputtering a first target including zinc oxide and a second target including indium oxide. The power ratio applied to the first target relative to the second target is between 2 and 10. In some embodiments, co-sputtering is performed in an environment substantially free from oxygen.

In some embodiments, after annealing, the first layer has a resistivity of less than about 400 microOhm-centimeters. Furthermore, after annealing, the first layer may have an absorption coefficient of less than 0.04% per nanometer. The refractive index may be between about 2.0 and 2.2 for the first layer after annealing. The first layer may have a thickness of between about 50 nanometers and 100 nanometers. The thickness may not change substantially during annealing. In some embodiments, the composition of the first layer is substantially uniform throughout the thickness of the first layer. Alternatively, the composition of the first layer may vary throughout a thickness of the first layer. For example, the concentration of indium oxide in the first layer may be higher closer to the surface of the epitaxial stack than away from the surface.

In some embodiments, the methods also involve forming a second layer partially covering the first layer. The second layer is operable as an electrode. The second layer may include gold.

Provided also are light emitting diodes including an epitaxial stack having a surface comprising gallium nitride. The light emitting diodes also include a current distribution layer disposed on and interfacing the surface of the epitaxial stack. The current distribution layer includes indium oxide and zinc oxide. The concentration of indium oxide in the current distribution layer is between about 5% and 15% by weight. The light emitting diodes also include an electrode disposed on the current distribution layer and partially covering the current distribution layer.

These and other embodiments are described further below with reference to the figures.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings.

FIG. 1 is a process flowchart of a method for fabricating an LED having a TCO layer formed from indium oxide and zinc oxide, in accordance with some embodiments.

FIG. 2 is a cross-sectional schematic view of a device used for fabricating an LED prior to forming a TCO layer, in accordance with some embodiments.

FIG. 3 is a cross-sectional schematic view of a device used for fabricating an LED after forming a TCO layer, in accordance with some embodiments.

FIG. 4 is a cross-sectional schematic view of a device used for fabricating an LED after forming an electrode above the TCO layer, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

An LED typically uses a thin conductive layer between a metal electrode and epitaxial stack. The metal electrode, while very conductive, is not transparent and cannot be disposed over the entire surface of the epitaxial stack. In fact, the area occupied by the electrode over the epitaxial stack should be minimized to reduce blockage of the light emitted from the epitaxial stack. At the same time, the epitaxial stack or, more specifically, the top surface of the epitaxial stack, which is often formed by gallium nitride, is not sufficiently conductive. As such, the thin conductive layer disposed between the metal electrode and epitaxial stack is used for current distribution. This layer is disposed over the entire top surface of the epitaxial stack and needs to be sufficiently transparent and conductive. When this layer is formed from oxide materials, the layer may be referred to as a transparent conductive oxide (TCO) layer.

These transparent conductive oxides are traditionally formed from nickel oxide or indium tin oxide. The forming process usually requires high annealing temperatures, such as above 400° C. and even above 500° C., in order to reduce oxide layer resistance and light absorption. However, high temperature annealing cuts into the thermal budget to the whole manufacturing process flow and may negatively impact the yield and process stability.

It has been found that combining amounts of indium oxide and zinc oxide in the same layer allows forming highly transparent and conductive layers without a need for high temperature annealing. Annealing temperatures of less than about 400° C. and even less than about 300° C. can be used for such layers without significant impact on the thermal budget. In some embodiments, the concentration of indium oxide in a formed layer is between about 5% and 15% by weight or, more specifically, between about 8% and 12% by weight, or even about 10% by weight. The layer may be deposited using two sputtering targets, e.g., one containing indium oxide and the one containing zinc oxide. In some embodiments, one sputtering target contains both indium oxide and zinc oxide. The weight ratio of indium oxide to zinc oxide in a sputtering target may be the same as in a deposited layer, in which case only one target is needed

### Processing Steps

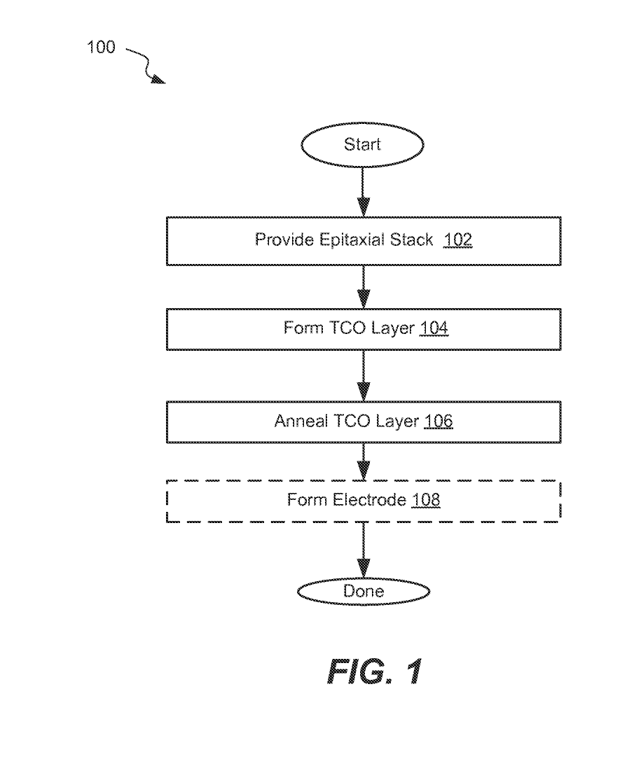

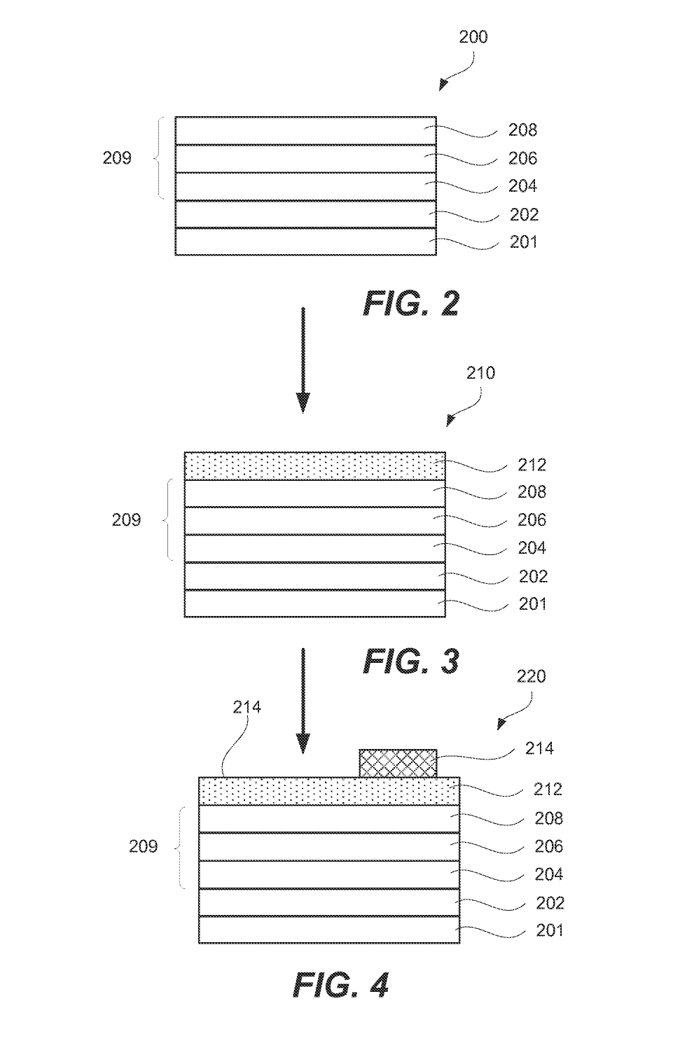

FIG. 1 is a process flowchart of method 100 for fabricating an LED having a TCO layer formed from indium oxide and zinc oxide, in accordance with some embodiments. One having ordinary skills in the art would appreciate that this method may be used for fabricating a TCO layer in other applications, such as solar cells. Method 100 may commence with providing an epitaxial stack during operation 102. The epitaxial stack may be a part of a device, such as a partially fabricated LED. One example of such device is shown in FIG. 2, which is a cross-sectional schematic view of device 200. Specifically, device 200 includes epitaxial stack 209 formed on substrate 202. Substrate 202 may include such materials as sapphire, silicon carbide, silicon, zinc oxide, magnesium oxide, aluminum nitride, gallium nitride, or combinations thereof. Substrate 202 may include other components, such as additional LEDs, electrical leads for supplying electrical power to epitaxial stack 209, control circuitry, and such. Back electrode 201 may be formed on the side substrate 202 that is opposite to epitaxial stack 209. Epitaxial stack 209 may include n-doped semiconductor 204 disposed over substrate 202. In some embodiments, n-doped semiconductor 204 directly interfaces substrate 202. Epitaxial stack 209 may also include active layer 206 disposed between n-doped semiconductor 204 and p-doped semiconductor 208. P-doped semiconductor 208 may form a surface for receiving a transparent conductive oxide layer formed in later operations. In some embodiments, the surface includes p-doped gallium nitride.

Method 100 may proceed with forming a transparent conductive oxide layer during operation 104. In order to differentiate the transparent conductive oxide layer from other components formed over this layer, the transparent conductive oxide layer may be referred to as a first layer, while the later formed components may be referred to as a second layer, third layer, and so on. The transparent conductive oxide layer may be formed by sputtering. Sputtering may be performed at a pressure of less than 5 mTorr or, more specifically, less than about 4 mTorr, such as between about 3 mTorr and 3.5 mTorr. In some embodiments, co-sputtering is performed in an environment with a controlled amount of oxygen, such as substantially free from oxygen or having a certain concentration of oxygen. Excessive amounts of oxygen in the sputtering environment may lead to a deposited film with an excessive resistance. TCOs are believed to get their conductivity in part from oxygen vacancies. As a result, more oxygen in the sputtering gas means less oxygen vacancies in the deposited film. Furthermore, target power and target to substrate spacing is controlled. The excessive power and/or close proximity between the target and substrate can lead to more high energy particles impinging on the surface and potentially worsen GaN/TCO interface quality.

In some embodiments, operation 104 involves co-sputtering a first target including zinc oxide and a second target including indium oxide. More specifically the first target may be made essentially of zinc oxide, while the second target may have equal weight amounts of zinc oxide and indium oxide. In this case, the power ratio applied to the transparent conductive oxide target relative to the second target may be between 2 and 10. Alternatively, a single target including zinc oxide and indium oxide may be used during operation 104. The concentration of indium oxide in this single target may be between about 5% and 15% by weight or, more specifically, between about 8% and 12% by weight, such as about 10% by weight. The rest of the target may be zinc oxide. In some embodiments, the composition of the target used during operation 104 is substantially the same as the composition of the resulting transparent conductive oxide layer.

Method 100 may proceed with annealing the transparent conductive oxide layer during operation 106. The annealing temperature may be less than about 500° C. (e.g., between about 100° C. and 500° C.) or, more specifically, at less than about 400° C. (e.g., between about 150° C. and 400° C.) or even at less than about 300° C. (e.g., between about 200° C. and 500° C.). As described above, low annealing temperatures are beneficial to reduce impact on the thermal budget. Without being restricted to any particular theory, it is believed that the mechanism of the conductivity improvement is thermally activated and may cease to occur when the temperature go below a certain lower threshold. In some embodiments, annealing is a rapid thermal annealing (RTA) process. For example, quartz lamps may be used for annealing. The annealing environment may include nitrogen.

FIG. 3 is a cross-sectional schematic view of device 210 after completing operation 106. Device 210 includes transparent conductive oxide layer 212 disposed on the surface of epitaxial stack 209. Specifically, the entire surface of epitaxial stack 209 may be covered by transparent conductive oxide layer 212.

After operation 106, the transparent conductive oxide layer includes indium oxide and zinc oxide. The concentration of indium oxide in the transparent conductive oxide layer may be between about 5% and 15% by weight or, more specifically, between about 8% and 12% by weight, such as about 10% by weight.

In some embodiments, the composition of the transparent conductive oxide layer is substantially uniform throughout the thickness of the transparent conductive oxide layer. Alternatively, the composition of the transparent conductive oxide layer may vary throughout a thickness of the transparent conductive oxide layer. For example, the concentration of indium oxide in the transparent conductive oxide layer may be higher closer to the surface of the epitaxial stack than away from the surface. Without being restricted to any particular theory, it is believed that indium oxide makes a better electrical contact (e.g., a lower resistivity) to p-done gallium nitride than, for example, zinc oxide.

The transparent conductive oxide layer may have a thickness of between about 50 nanometers and 100 nanometers. The thickness may not change substantially during annealing. In some embodiments, after operation 106, the transparent conductive oxide layer has a resistivity of less than about 400 microOhm-centimeters or even less than about 200 microOhm-centimeters. This combination of the thickness and resistivity may be sufficient to achieved current distribution functions described above.

After operation 106, the transparent conductive oxide layer may have an absorption coefficient of less than 0.04% per nanometer or, more specifically, less than 0.02% per nanometer. Even at 100 nanometer thick, the absorption coefficient is less than 4% allowing a large portion of light to pass from, for example, the epitaxial stack disposed under the transparent conductive oxide layer. In some embodiments, the refractive index of transparent conductive oxide layer may be between about 2.0 and 2.2.

Method 100 may proceed with forming another layer (i.e., a second layer) over the transparent conductive oxide layer during optional operation 108. The second layer may partially cover the transparent conductive oxide layer. The second layer is operable as an electrode. The second layer may include gold. FIG. 4 is a cross-sectional schematic view of device 400 having electrode 214 disposed above transparent conductive oxide layer 212, in accordance with some embodiments.

### Experimental Results

Various experiments have been conducted to study resistivity and absorption coefficient of TCO layers prepared using different processes. Glass or sapphire substrates have been used for depositing these TCO layers. In the first experiment, TCO layers having different compositions of indium oxide and zinc oxide have been tested. The weight ratio of indium oxide was varied from 0% (i.e., pure zinc oxide) to 50% (i.e., the same weight amounts of indium oxide and zinc oxide). The composition was varied by using different power levels for sputtering targets. One target included pure zinc oxide, while another target was formed from the same weight amounts of indium oxide and zinc oxide. Substantially no oxygen was present in the deposition environment. The deposition rates were about 1.5-2 Angstroms per second. The TCO layers have been deposited using two different pressure levels (3 mTorr and 5 mTorr) and then subjected to different annealing temperatures (350° C. and 450° C.). The result of this experiment is presented Table 1 below.

TABLE 1

| | Resistivity, | | | | Absorption | | | |
|---|---|---|---|---|---|---|---|---|
| | microOhm-cm | | | | Coefficient (%/nm) | | | |
| | Anneal at | | Anneal at | | Anneal at | | Anneal at | |
| | 350° C. | | 450° C. | | 350° C. | | 450° C. | |
| In₂O₃, | 5 | 3 | 5 | 3 | 5 | 3 | 5 | 3 |
| wt % | Torr | Torr | Torr | Torr | Torr | Torr | Torr | Torr |
| 0% | 2344 | 1296 | 1592 | 1033 | 0.326 | 0.179 | 0.113 | 0.130 |
| 8.5-10.1% | 1635 | 1348 | 1571 | 945 | 0.133 | 0.065 | 0.133 | 0.072 |
| 16.9-19.4% | 1794 | 1473 | 1373 | 1063 | 0.055 | 0.080 | 0.049 | 0.083 |
| 25.2-27.9% | 1870 | 2329 | 1201 | 1550 | 0.034 | 0.014 | 0.025 | 0.016 |
| 33.5-35.8% | 1326 | 4620 | 889 | 1613 | 0.109 | 0.021 | 0.025 | 0.014 |
| 41.8-43.2% | 1377 | 1784 | 698 | 818 | 0.189 | 0.063 | 0.053 | 0.012 |
| 50% | 1651 | 1136 | 649 | 682 | 0.237 | 0.166 | 0.089 | 0.017 |

It is generally desirable to have lower resistivity and absorption. The experimental results presented in the table above indicate that the deposition pressure, post deposition annealing temperature, and composition of the TCO layer can all impact both of these characteristics. Specifically, adding indium oxide into zinc oxide generally helps with reducing the resistivity and absorption when comparing to pure zinc oxide (0 wt % for In₂O₃). However, both resistivity and absorption tend to increase when large amounts of indium oxide are added to zinc oxide (e.g., high resistivity for 25.2-27.9 wt % samples and high absorption coefficient for samples having more than 25.2-27.9 wt % of indium oxide). It appears that the best combination of resistivity and absorption was achieved for samples that had 8.5-10.1 wt % of indium oxide, deposited at 3 mTorr, and annealed at 350° C. or 450° C.

Since the annealing temperature appears to a major factor in achieving low resistivity and absorption and since the annealing temperature generally needs to be minimized to preserve the thermal budget of the overall device including a TCO layer, the effects of annealing temperatures have been studied further for samples having about 10 wt % of indium oxide and formed at a pressure of 3-3.5 mTorr. The results of this second experiment are presented in Table 2 below. Seven samples were tested for each annealing temperature to determine averages and deviations from these averages for resistivity and absorption.

TABLE 2

| Annealing | Resistivity, | Absorption |
|---|---|---|
| Conditions | microOhm-cm | Coefficient (%/nm) |
| No Anneal | 410-949 | 0.026-0.101 |
| 150° C. | 374-914 | 0.012-0.083 |
| 200° C. | 330-774 | 0.016-0.088 |
| 250° C. | 308-494 | 0.005-0.065 |
| 300° C. | 302-372 | 0.002-0.025 |
| 350° C. | 294-345 | 0.025-0.051 |
| 450° C. | 280-431 | 0.015-0.064 |

From the resistivity results presented in Table 2, it appears that annealing temperatures greater than 250° C. are acceptable for TCO layers having 10 wt % of indium oxide. However, annealing at 450° C. seems to be detrimental for absorption and result in high adsorption coefficient for some samples. As such, it is believed that annealing temperature of less than 400° C. or even less than 300° C. would be more suitable from the absorption stand point.

### Conclusion

Although the foregoing examples have been described in some detail for purposes of clarity of understanding, the invention is not limited to the details provided. There are many alternative ways of implementing the invention. The disclosed examples are illustrative and not restrictive.

1. A method of fabricating a light emitting diode, the method comprising:
forming a first layer using sputtering,
wherein the first layer comprises indium oxide and zinc oxide,
wherein a concentration of indium oxide in the first layer is between about 5% and 15% by weight,
wherein the first layer is formed on a surface of an epitaxial stack,
wherein the surface comprises gallium nitride; and
annealing the first layer at a temperature of between about 100° C. and 500° C.

2. The method of claim 1, wherein the concentration of indium oxide in the first layer is between about 8% and 12% by weight.

3. The method of claim 1, wherein the concentration of indium oxide in the first layer is about 10% by weight.

4. The method of claim 1, wherein annealing the first layer is performed at the temperature of between about 150° C. and 400° C.

5. The method of claim 1, wherein annealing the first layer is performed at the temperature of between about 200° C. and 300° C.

6. The method of claim 1, wherein forming the first layer comprises co-sputtering a first target comprising zinc oxide and a second target comprising indium oxide.

7. The method of claim 6, wherein a ratio of power applied to the first target to power applied to the second target is between 2 and 10.

8. The method of claim 6, wherein co-sputtering is performed in an environment substantially free from oxygen.

9. The method of claim 1, wherein sputtering is performed at a pressure of less than 5 mTorr.

10. The method of claim 1, wherein, after annealing, the first layer has a resistivity of less than about 400 microOhm-centimeters.

11. The method of claim 1, wherein, after annealing, the first layer has an absorption coefficient of less than 0.04% per nanometer.

12. The method of claim 1, wherein, after annealing, the first layer has a refractive index of between about 2.0 and 2.2.

13. The method of claim 1, wherein the first layer has a thickness of between about 50 nanometers and 100 nanometers.

14. The method of claim 1, wherein a composition of the first layer is substantially uniform throughout a thickness of the first layer.

15. The method of claim 1, wherein a composition of the first layer varies throughout a thickness of the first layer.

16. The method of claim 15, wherein the concentration of indium oxide in the first layer is higher closer to the surface of the epitaxial stack than away from the surface.

17. The method of claim 1, wherein the surface comprises p-doped gallium nitride.

18. The method of claim 1, further comprising forming a second layer partially covering the first layer, wherein the second layer is operable as an electrode.

19. The method of claim 18, wherein the second layer comprises gold.

20. (canceled)
